(19) United States
(12) Patent Application Publication
(10) Pub. No.: US 2026/0128107 A1
(43) Pub. Date: May 7, 2026

(54) METHODS AND SYSTEMS TO PERFORM THRESHOLD VERIFICATION USING MULTI-LEVEL SENSING OF MEMORY CELLS

(71) Applicant: Micron Technology, Inc., Boise, ID (US)

(72) Inventor: Jisuk Kim, San Jose, CA (US)

(73) Assignee: Micron Technology, Inc., Boise, ID (US)

(21) Appl. No.: 19/363,557

(22) Filed: Oct. 20, 2025

Related U.S. Application Data
(60) Provisional application No. 63/717,802, filed on Nov. 7, 2024.

(51) Int. Cl. G11C 16/34; G11C 16/08; G11C 16/26; G11C 16/30

(52) U.S. Cl. CPC G11C 16/3459; G11C 16/08; G11C 16/26; G11C 16/30

(57) ABSTRACT

Methods, systems, and devices for techniques for faster voltage threshold verification are provided. In one embodiment, a memory device comprises a memory cell and page buffer. The memory cell is coupled to a word line to receive a word voltage corresponding to a first level of the memory cell. The page buffer is coupled to a bit line associated with the memory cell. The page buffer comprises a sense amplifier configured to sense a current of the bit line. The sense amplifier is configured to determine a voltage of the sense amplifier based on the current at a first point in time that corresponds to a PV voltage of the first level. The sense amplifier is configured to determine the circuit voltage of the sense amplifier based on the current at a second point in time that corresponds to a SPPV voltage of a second level of the memory cell.

### CROSS-REFERENCE TO RELATED APPLICATIONS

This application claims priority to U.S. Provisional Application No. 63/717,802, filed on Nov. 7, 2024, entitled “METHODS AND SYSTEMS TO PERFORM THRESHOLD VERIFICATION USING MULTI-LEVEL SENSING OF MEMORY CELLS,” the contents of which is incorporated by reference in its entirety for all purposes.

### TECHNICAL FIELD

This disclosure relates to one or more systems for memory, including techniques for methods and systems to perform threshold verification using multi-level sensing of memory cells.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, program verify, retrieve, determine, etc.) states from the memory cells. To store information, the memory device may write (e.g., program, set, assign, etc.) states to the memory cells. Information can also be erased from the memory cells and new information can be stored in the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 is a block diagram of a memory device in communication with a memory system controller of a memory system, in accordance with examples as disclosed herein.

FIGS. 2A-2C are illustrative schematics of portions of an array of memory cells in a memory device, in accordance with examples as disclosed herein.

FIG. 2D illustrates an example of a memory device including multiple blocks of memory cells in accordance with examples as disclosed herein.

FIG. 3 illustrates a graphical representation of a circuit voltage over a period of time during threshold verification, in accordance with examples as disclosed herein.

FIG. 4 illustrates a graphical representation of example cell distributions and example verification levels that correspond to various logical levels, in accordance with examples as disclosed herein.

FIG. 5 illustrates a graphical representation of cell distributions of example logical levels of three cells of an array of memory cells, in accordance with examples as disclosed herein.

FIG. 6 illustrates a flowchart showing a method that supports techniques for performing threshold verification using multi-level sensing of a memory cell, in accordance with examples as disclosed herein.

### DETAILED DESCRIPTION

Memory devices can use cell distributions of threshold voltages (Vt) corresponding to memory cells to determine a current logical level of the memory cells. The cell distributions of the threshold voltages indicate voltage levels that, when applied to select gates of corresponding memory cells programmed at particular logical levels, cause the memory cells (e.g., transistors that form the memory cells) to conduct and be read, written to, or both. For example, the threshold voltages of the memory cells programmed at a logical level of logic 010 (e.g., a lower logical lever) may be between 1.4 volts (V) and 1.8V and the threshold voltage of the memory cells programmed at a logical level of 011 (e.g., a higher logical level) may be between 1.9V and 2.3V.

A memory device can verify (e.g., determine) the cell distributions of the threshold voltages by performing programming loops. For example, during each of the programming loops, a controller of the memory device causes predetermined voltages (e.g., in the form of program pulses) to be applied to word lines connected to the memory cells at different verification levels that correspond to different logical levels. These predetermined voltages are also referred to as the word line voltages. In one example, as described in greater detail below, multiple verification levels may correspond to a same logical level. Thus, a first verification level and a second verification level of the word line voltages may both correspond to a first logical level. A third verification level of the word line voltages may correspond to a second logical level. In this above example, two verification levels correspond to one logical level. In other examples, three verification levels may correspond to one logical level. As described below, the greater number of verification levels may provide higher determination accuracy of cell distribution for threshold voltages, but may cause longer delay.

During programming loops, the controller may cause sensing of a current on one or more bit lines electrically coupled to the memory cells to determine if the memory cells are conducting at the different verification levels. For example, a sense amplifier of the memory devices may sense (e.g., read, detect, measure, retrieve, program verify, or determine) the currents on the bit lines. In accordance with current sensed by the sense amplifier, the controller of the memory device may cause adjustment of the bit line voltages to control the current on the bit lines for subsequent programming loops. Controlling the current on the bit lines can limit (e.g., reduce), or prevent (e.g., inhibit) changes in the current on the bit lines that occur during the subsequent programming loops.

Next, the example of two verification levels corresponding to one logic level is described. During programming loops, a sense amplifier of a memory device may sense the current on the bit lines for only two verification levels per logical level. For example, a controller of the memory device can determine if the memory cells are conducting for only a pre-program verify (PPV) voltage verification level (generally referred to in the present disclosure as a first PPV (FPPV) voltage) and a program verify (PV) voltage verification level (generally referred to in the present disclosure as the PV voltage) for each logical level. In addition, during programming loops, a controller of the memory device may cause the word line voltage to be applied at the two verification levels to permit the sense amplifier to sense the current on the bit lines for the two different verification levels. However, if the controller determines whether the memory cells are conducting for only two different verification levels per logical level, the determination of the accuracy of the cell distributions of threshold voltages may be reduced. Moreover, it may introduce errors during subsequent operations of the memory device.

In certain technologies, three verification levels are used to improve the determination accuracy. In particular, during programming loops, the sense amplifier of a memory device may sense the current on the bit lines for three verification levels per logical level. For example, the controller of a memory device may determine if the memory cells are conducting for a super PPV voltage verification level (generally referred to in the present disclosure as a second PPV (SPPV) voltage), the FPPV voltage, and the PV voltage for each logical level of the memory cells. Thus, during programming loops, a controller of the memory device may cause the word line voltage to be applied at each of the three verification levels (SPPV, FPPV, and PV) to permit the sense amplifier to sense the current on the bit lines for the three different verification levels. Compared to that of two verification levels per logical level, determining if the memory cells are conducting for three verification levels per logical level can increase an accuracy of the cell distributions and reduce errors during subsequent operations of the memory device. However, during such an operation, the controller needs to cause the word line voltage to be applied at each of the three verification levels per logical level. As a result, the amount of time to verify the cell distributions of the threshold voltages is increased compared to that of sensing the current on the bit lines for only two different verification levels per logical level. In other words, sensing the current on the bit lines for three verification levels per logical level may cause additional delay compared to applying to just two verification levels.

Another limiting factor for sensing bit line current for three verification levels relates to the sense amplifier's sensing range capability. During programming loops, to determine if the bit lines are conducting current, the sense amplifier of a memory device may determine a circuit voltage (e.g., a node voltage) at the input of the sense amplifier at different points in time while a word line voltage corresponding to a particular logical level is being applied. For example, the sense amplifier of the memory device may determine if the circuit voltage reduces (e.g., drops) at the different points in time to determine if the bit lines are conducting current. Each of the different points in time may correspond to a different verification level of the particular logical level. However, the sense amplifier may have a limited sensing range capability and a potential difference of the circuit voltage between three different verification levels of a particular logical level may be greater than the sensing range capability of the sense amplifier. For example, the potential difference of the circuit voltage between three verification levels of a particular logical level may be four hundred millivolts (mV) and the sensing range capability of the sense amplifier may be limited to seventy mv. As a result, the limited sensing range capability of the sense amplifier may prevent the sense amplifier from being able to determine the circuit voltage that corresponds to each of the three verification levels of a particular logical level, while a single word line voltage corresponding to the particular logical level is being applied to the memory cells.

To compensate for the limited sensing range capability of the sense amplifier, during programming loops, the controller causes a first word line voltage associated with the particular logical level to be applied to the word line connected to the memory cells and the sense amplifier determines the circuit voltage at two points in time that correspond to two of the verification levels of the particular logical level. Subsequently, during programming loops, the controller causes a second word line associated with the particular logical level to be applied to the word line connected to the memory cells and the sense amplifier determines the circuit voltage at another point in time that corresponds to another verification level of the particular logical level. Thus, to mitigate the limited sensing range of the sense amplifier, the controller causes two word line voltages to be applied for three verification levels per logical level. While this technology may solve the problem of limited sensing range, it may also increase an amount of time that is used to verify the cell distribution of the memory cells compared to the controller causing just one word line voltage to be applied per logical level for all three verification levels.

The present disclosure provides techniques for avoiding or reducing the technical difficulties described above. In particular, some embodiments described in the present disclosure include a memory device that, during programming loops, is configured to sense the circuit voltage at different points in time that correspond to multiple verification levels of multiple logical levels, while applying a word line voltage that corresponds to a single logical level. For instance, a local controller of the memory device causes a word line voltage to be applied that corresponds to a first logical level. In these and other embodiments, a sense amplifier of the memory device determines the circuit voltage at different points in time that correspond to multiple verification levels of the first logical level and a second logical level, while the word line voltage that corresponds to the first logical level is being applied. For example, the sense amplifier may determine the circuit voltage at a first point in time that corresponds to the FPPV voltage of the first logical level, a second point in time that corresponds to the PV voltage of the first logical level, or a third point in time that corresponds to the SPPV voltage of the second logical level. The sense amplifier can perform such a determination because a value of the SPPV voltage of the second logical level may be the same, similar to, or close to a value of the PV voltage of the first logical level. Such an overlapping of verification voltage levels at different logical levels in turn reduces the potential difference of the circuit voltages of the sense amplifier between multiple verification levels of multiple logical levels. For instance, the SPPV voltage of the second logical level may be the same, similar to, or close to the PV voltage of the first logical level. As a result, it may reduce the potential difference of the circuit voltages between three verification levels of two logical levels compared to the potential difference of the circuit voltages between three verification levels of a single logical level. The potential difference between the circuit voltages between three verification levels of a single logical level may be one and half times or two times the potential differences between three verification levels of two logical levels. In one example, the potential difference of the circuit voltages between three verification levels that correspond to two logical levels may be 0.2V and the potential difference of the circuit voltage between the three verification levels that correspond to a single logical level may be 0.5V. The reduction of the circuit voltage differences (e.g., the voltage differences at the input node of the sense amplifier) alleviate or eliminate the limited sensing voltage capability problem of the sense amplifier.

During a programming loop, the local controller may identify logical levels to use for verifying the cell distribution of the threshold voltage of a present logical level of the memory cells. For example, the local controller may identify that the first logical level and the second logical level of the memory cells are to be verified. The local controller may cause a regulator of the memory device to apply a word line voltage that corresponds to a lower logical level of the identified logical levels. In other words, the regulator may pre-charge the word line to a voltage level that corresponds to the lower logical level of the identified logical levels. For example, the regulator may apply the word line voltage at the PV voltage of the first logical level.

As described above, the sense amplifier may sense the current of the bit lines. In addition, the sense amplifier may determine the circuit voltage of the sense amplifier at different points in time that correspond to different verification levels of a lower logical level and a higher logical level, using only the word line voltage that corresponds to the lower logical level. In other words, the sense amplifier may permit the circuit voltage to develop and be sensed for three verification levels that correspond to two logical levels while applying a single word line voltage. For example, the sense amplifier may determine the circuit voltage at a first point in time that corresponds to the FPPV voltage of the first identified logical level, at a second point in time that corresponds to the PV voltage of the first identified logical level, and/or at a third point in time that corresponds to the SPPV voltage of the second identified logical level, all while the controller causes only the word line voltage at the PV voltage of the first identified logical level is applied.

As illustrated above, the memory device described in the present disclosure is configured to perform the threshold voltage verification by sensing the circuit voltage at different points in time that correspond to multiple verification levels of different logical levels without changing the word line voltage. As a result, the technologies described herein may increase a determination accuracy of the cell distributions for the threshold voltages compared to determining the cell distribution at only two different verification levels. Unlike some existing technologies, the increasing in cell distribution determination accuracy does not come at the cost of increasing of time delay for such a determination. As described briefly above and more in detail below, the techniques disclosed herein enable a memory device described to reduce an amount of time and/or latency to verify the threshold voltages by not having to adjust the word line voltage multiple times per programming loop.

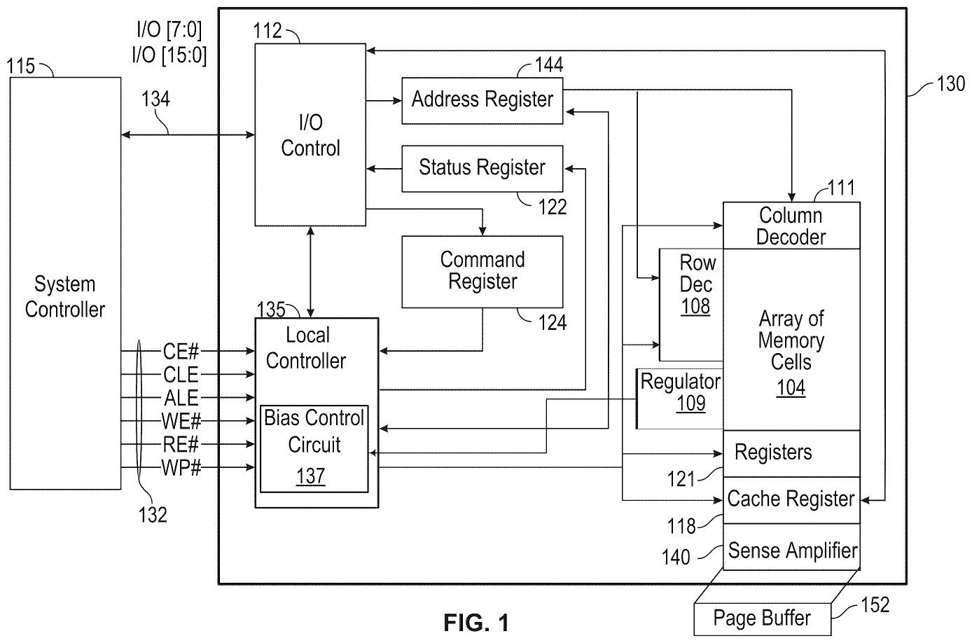

FIG. 1 is a simplified block diagram of a memory device 130 in communication with a system controller 115 of a memory system according to an embodiment. A memory system may be or include any device or collection of devices, where the device or collection of devices includes at least one memory array. For example, a memory system may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices. A memory system may communicate with a host system, which may include a host system controller. The host system may be implemented using one or more processors and a memory system for writing data to the memory system, reading data from the memory system, erasing data, or refreshing data.

A memory system may include one or more memory devices, such as memory device 130. The memory device 130 may include one or more memory arrays of any type of memory cells (e.g., non-volatile memory cells, volatile memory cells, or any combination thereof). For example, the memory device 130 may include NAND (e.g., NAND flash) memory, ROM, phase change memory (PCM), NOR (e.g., NOR flash) memory, etc. In some cases, the memory device 130 is a NAND memory device 130, may include memory cells configured to each store one bit of information, which may be referred to as single level cells (SLCs). Additionally, or alternatively, the NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

As shown in FIG. 1 and described below in more detail, the memory device 130 includes an array of memory cells 104 logically arranged in rows and columns. Memory cells of a logical row are typically connected to the same access line (e.g., a word line) while memory cells of a logical column are typically selectively connected to the same data line (e.g., a bit line). A single access line can be associated with more than one logical row of memory cells and a single data line can be associated with more than one logical column. Memory cells (not shown in FIG. 1) of at least a portion of the array of memory cells 104 are capable of being programmed to one of at least two target data states for storing any number of bits of information.

With continued reference to FIG. 1, row decode circuitry 108 and column decode circuitry 111 are provided to decode address signals. Address signals are received and decoded to access the array of memory cells 104. Memory device 130 also includes input/output (I/O) control circuitry 112 to manage input of commands, addresses, and data to memory device 130 as well as output of data and status information from memory device 130. An address register 144 is in communication with I/O control circuitry 112 and row decode circuitry 108 and column decode circuitry 111 to latch the address signals prior to decoding. The row decode circuitry 108 and the column decode circuitry 111 may simply be referred to as a row decoder 108 and a column decoder 111, respectively. A command register 124 is in communication with the I/O control circuitry 112 and a local controller 135 to latch incoming commands.

A memory controller (e.g., the local controller 135 internal to memory device 130) controls access to the array of memory cells 104 in response to the commands and generates status information for the external system controller 115, i.e., the local controller 135 is configured to perform access operations (e.g., read operations, programming operations, and/or erase operations) on the array of memory cells 104. The local controller 135 is in communication with row decode circuitry 108 and the column decode circuitry 111 to control the row decode circuitry 108 and the column decode circuitry 111 according to the addresses.

In some embodiments, the local controller 135 may further include a bias control circuit 137 in communication with a regulator 109. The regulator 109 may apply particular biasing voltages or currents to the word lines, the bit lines, or both that are coupled to the array of memory cells 104. The regulator 109 may be controlled by the memory controller according to the addresses provided by the row decode circuitry 108 and the column decode circuitry 111. For example, the regulator 109 may apply biasing voltages and/or currents to certain word lines and bit lines for selected memory cells to perform read, write, program, and erase operations. The regulator 109 may include one or more circuits for generating biasing voltages and currents and for regulating or driving the word lines and bit lines of the selected memory cells.

In some embodiments, the local controller 135 communicates with the external system controller 115, which may be a host controller (e.g., an UFS or eMMC controller, or a CPU communicating with the local controller 135) located in a host system or a memory system controller located in a memory system. In some embodiments, the local controller 135 is disposed on the same semiconductor die as the memory array (e.g., array of memory cells 104), and a separate system controller 115 is disposed on a different die. In other examples, some portions of the memory device 130 may be disposed on a first die and other portions of the memory device 130 may be disposed on a second die different from the first die. For instance, the first die may include the array of memory cells 104 and its associated circuitry such as the column decoder 111 and the row decoder 108, etc. The second die may include logic circuitry, power circuitry, or other circuitry of the memory device 130. Thus, the second die may include the system controller 115, the I/O control circuitry 112, etc. In this example, the first die has no local controller, and the second die includes the system controller 115. The first die and the second die can be hybrid bonded together using, for example, through-hole vias (TSVs) such that they are electrically connected. The first die and the second die may also be wafer-bonded using flip-chip bonding technologies, etc. In this disclosure, the system controller 115 and the local controller 135 may both be referred to as memory controllers, or a first memory controller and a second memory controller, for simplicity. It is understood that while they may be different controllers, certain operations disclosed herein may be caused or performed by either or both memory controllers, unless otherwise specified.

The local controller 135 is also in communication with a cache register 118, registers 121, and a sense amplifier 140. In some embodiments, one or more cache registers 118 can collectively form at least a part of a cache buffer. The cache register 118 latches or buffers data, either incoming or outgoing, as directed by the local controller 135 to temporarily store data while the array of memory cells 104 is busy writing or reading, respectively, other data. During a program operation (e.g., write operation), data can be passed from the cache register 118 to the registers 121 for transfer to the array of memory cells 104; then new data can be latched in the cache register 118 from the I/O control circuitry 112. During a read operation, data can be passed from the cache register 118 to the I/O control circuitry 112 for output to the system controller 115; then new data can be passed from the registers 121 to the cache register 118. In some embodiments, the cache register 118 and/or the registers 121 can form at least a portion of a page buffer 152 of the memory device 130. The sense amplifier 140 may be configured to sense a data state of a memory cell of the array of memory cells 104, e.g., by sensing a state of a data line (e.g., bit lines) connected to that memory cell. Sense amplifier 140 is described in more detail below. A status register 122 can be in communication with I/O control circuitry 112 and the local controller 135 to latch the status information for output to system controller 115.

As shown in FIG. 1, memory device 130 receives various control signals via local the local controller 135 from the system controller 115 over a control link 132. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) can be further received over the control link 132 depending upon the nature of the memory device 130. In one embodiment, the memory device 130 receives command signals (which represent commands), address signals (which represent addresses), and data signals (which represent data) from the system controller 115 over a multiplexed input/output (I/O) bus 134 and outputs data to the system controller 115 over the I/O bus 134.

For example, the commands can be received over input/output (I/O) pins [7:0] of the I/O bus 134 at the I/O control circuitry 112 and can then be written into a command register 124. The addresses can be received over input/output (I/O) pins [7:0] of the I/O bus 134 at the I/O control circuitry 112 and can then be written into the address register 144. The data can be received over input/output (I/O) pins [7:0] for an 8-bit device or input/output (I/O) pins [15:0] for a 16-bit device at the I/O control circuitry 112 and then can be written into the cache register 118. The data can be subsequently written into the registers 121 for programming the array of memory cells 104.

In an embodiment, the cache register 118 can be omitted, and the data can be written directly into the registers 121. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 130 by an external device (e.g., the system controller 115), such as conductive pads or conductive bumps as are commonly used. While the above description uses 16 bits I/O bus 134 as an example, it is understood that bus 134 can be configured to any number of bits (e.g., 64 bits).

It will be appreciated by those skilled in the art that additional circuitry and signals can be provided, and that memory device 130 of FIG. 1 has been simplified. It should be recognized that the functionality of the various block components described with reference to FIG. 1 may not necessarily be segregated to distinct components or component portions of an integrated circuit device. For example, a single component or component portion of an integrated circuit device could be adapted to perform the functionality of more than one block component of FIG. 1. Alternatively, one or more components or component portions of an integrated circuit device could be combined to perform the functionality of a single block component of FIG. 1. Additionally, while specific I/O pins are described in accordance with popular conventions for receipt and output of the various signals, it is noted that other combinations or numbers of I/O pins (or other I/O node structures) can be used in the various embodiments.

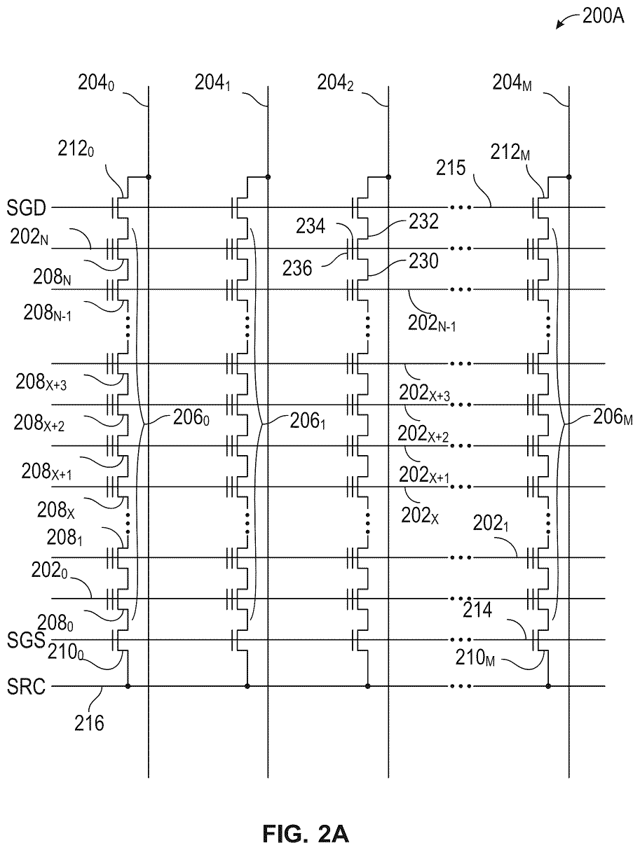

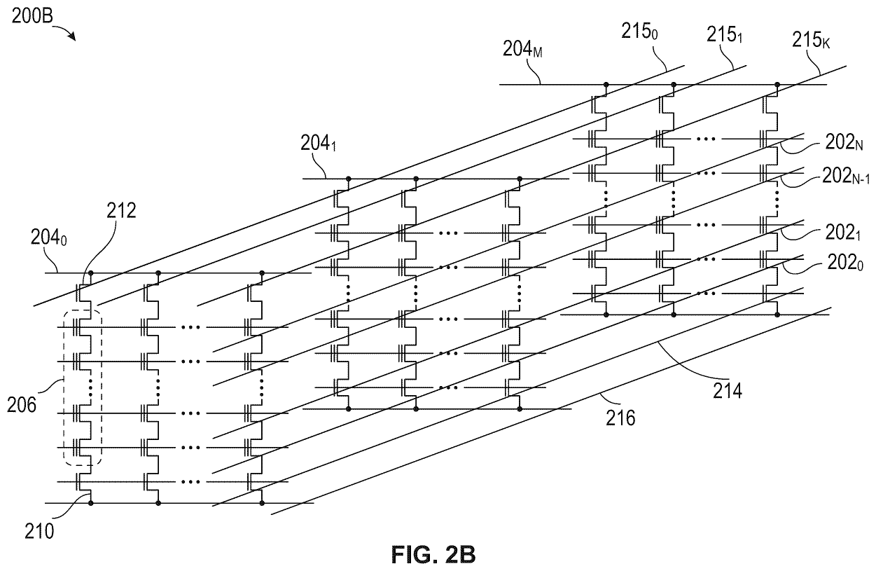

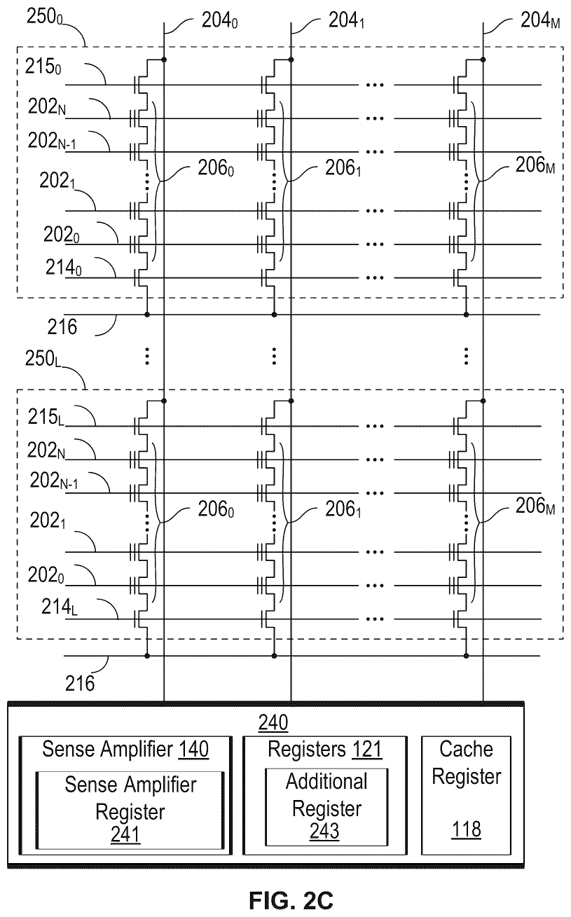

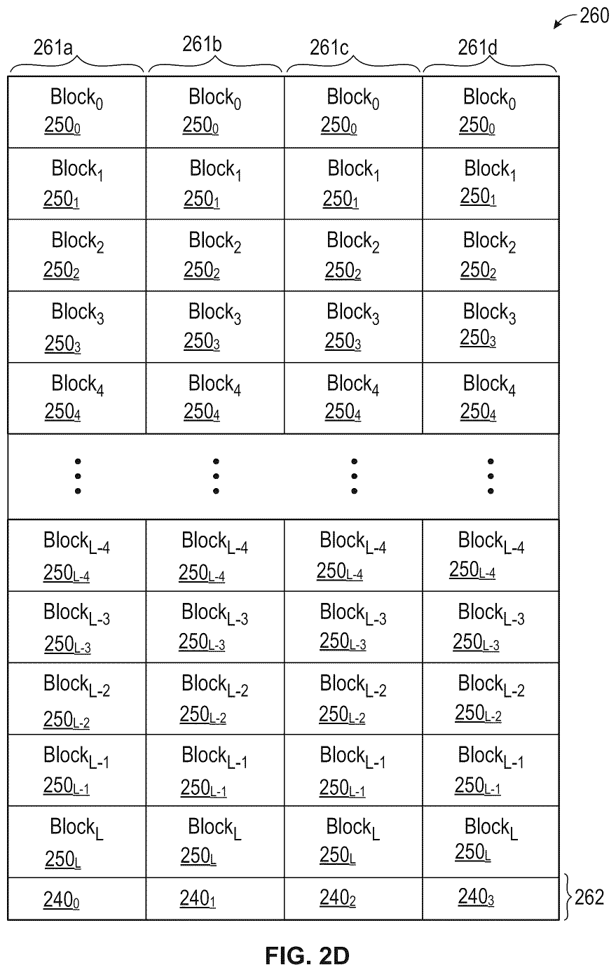

FIGS. 2A-2B are example schematics of portions of an array of memory cells 200A, such as a NAND memory array. Array of memory cells 200A may be an example of the array of memory cells 104 of a memory device 130 as described with reference to FIG. 1 according to an embodiment. Memory array 200A includes access lines, such as word lines 202₀ to 202_{N}, and data lines, such as bit lines 204₀ to 204_{M}. The word lines 202 can be connected to global access lines (e.g., global word lines), not shown in FIG. 2A, in a many-to-one relationship. For some embodiments, memory array 200A can be formed over a semiconductor that, for example, can be doped to have a conductive type, such as a p-type conductivity, e.g., to form a p-well, or an n-type conductivity, e.g., to form an n-well.

Memory array 200A can be arranged in rows (each corresponding to a word line 202) and columns (each corresponding to a bit line 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select transistor 210 (e.g., a field-effect transistor), such as one of the select gates 210₀ to 210_{M} (e.g., that can be source select transistors, commonly referred to as select gate source), and a select transistor 212 (e.g., a field-effect transistor), such as one of the select transistors 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select transistors 210 and 212 can utilize a structure similar to (e.g., the same as) the memory cells 208. The select transistors 210 and 212 can represent a number of select gates connected in series, with each select transistor in series configured to receive a same or independent control signal.

A source of each select transistor 210 can be connected to common source 216. The drain of each select transistor 210 can be connected to a memory cell 208₀ of the corresponding NAND string 206. For example, the drain of select gate 210₀ can be connected to memory cell 208₀ of the corresponding NAND string 206₀. Therefore, each select transistor 210 can be configured to selectively connect a corresponding NAND string 206 to the common source 216. A control gate of each select transistor 210 can be connected to select line 214.

The drain of each select transistor 212 can be connected to bit line 204 for the corresponding NAND string 206. For example, the drain of select gate 212₀ can be connected to the bit line 204₀ for the corresponding NAND string 206₀. The source of each select transistor 212 can be connected to a memory cell 208_{N} of the corresponding NAND string 206. For example, the source of select gate 212₀ can be connected to memory cell 208_{N} of the corresponding NAND string 206₀. Therefore, each select transistor 212 can be configured to selectively connect a corresponding NAND string 206 to the corresponding bit line 204. A control gate of each select transistor 212 can be connected to select line 215.

The memory array 200A in FIG. 2A can be a quasi-two-dimensional memory array and can have a generally planar structure, e.g., where the common source 216, NAND strings 206 and bit lines 204 extend in substantially parallel planes. Alternatively, the memory array 200A in FIG. 2A can be a three-dimensional memory array, e.g., where NAND strings 206 can extend substantially perpendicular to a plane containing the common source 216 and to a plane containing the bit lines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2A. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. Memory cells 208 have their control gates 236 connected to (and in some cases form) a word line 202.

A column of the memory cells 208 can be a NAND string 206 or a number of NAND strings 206 selectively connected to a given bit line 204. A row of memory cells 208 can be memory cells 208 commonly connected to a given word line 202. A row of memory cells 208 can, but need not, include all the memory cells 208 commonly connected to a given word line 202. Rows of memory cells 208 can often be divided into one or more groups of physical pages of memory cells 208, and physical pages of the memory cells 208 often include every other memory cell 208 commonly connected to a given word line 202. For example, the memory cells 208 commonly connected to word line 202_{N} and selectively connected to even bit lines 204 (e.g., bit lines 204₀, 204₂, 204₄, etc.) can be one physical page of the memory cells 208 (e.g., even memory cells) while memory cells 208 commonly connected to word line 202_{N} and selectively connected to odd bit lines 204 (e.g., bit lines 204₁, 204₃, 204₅, etc.) can be another physical page of the memory cells 208 (e.g., odd memory cells).

Although bit lines 204₃-204₅ are not explicitly depicted in FIG. 2A, it is apparent from the figure that the bit lines 204 of the array of memory cells 200A can be numbered consecutively from bit line 204₀ to bit line 204_{M}. Other groupings of memory cells 208 commonly connected to a given word line 202 can also define a physical page of memory cells 208. For certain memory devices, all memory cells commonly connected to a given word line can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to word lines 202₀-202_{N} (e.g., all NAND strings 206 sharing common word lines 202). Unless expressly distinguished, a reference to a page of memory cells herein refers to the memory cells of a logical page of memory cells. A logical page may or may not be the same as a physical page. Although the example of FIG. 2A is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

FIG. 2B is another schematic of a portion of an array of memory cells 200B as could be used in the memory device 130, e.g., as a portion of the array of memory cells 104. Like numbered elements in FIG. 2B correspond to the description as provided with respect to FIG. 2A. FIG. 2B provides additional detail of one example of a three-dimensional NAND memory array structure. Three-dimensional NAND memory array 200B can incorporate vertical structures which can include semiconductor pillars where a portion of a pillar can act as a channel region of the memory cells of NAND strings 206. NAND strings 206 can be each selectively connected to a bit line 204₀-204_{M} by a select transistor 212 (e.g., that can be drain select transistors, commonly referred to as select gate drain) and to a common source 216 by a select transistor 210 (e.g., that can be source select transistors, commonly referred to as select gate source). Multiple NAND strings 206 can be selectively connected to the same bit line 204. Subsets of NAND strings 206 can be connected to their respective bit lines 204 by biasing the select lines 215₀-215_{K} to selectively activate particular select transistors 212 each between a NAND string 206 and a bit line 204. The select transistors 210 can be activated by biasing the select line 214. In some embodiments, each sub-block or string of memory cells has a separate select line 214 from other sub-blocks or strings. In some embodiments, a pair of sub-blocks shares a select line 214. Each word line 202 can be connected to multiple rows of memory cells of the memory array 200B. Rows of memory cells that are commonly connected to each other by a particular word line 202 can collectively be referred to as tiers.

The three-dimensional NAND memory array 200B may include multiple stacked layers of levels of memory cells and connected using vertical channels such as semiconductor pillars. The number of layers in three-dimensional NAND memory array 200B can be, for example, 32, 48, 64, 96, 112 layers, or any number of layers. In some examples, a group of layers may be collectively referred to as a deck. A deck in a three-dimensional NAND memory array may be processed together (e.g., etched together for forming a portion of the semiconductor pillar). A memory device having three-dimensional NAND memory arrays can provide more memory cells on a single chip than a memory device formed by two-dimensional NAND arrays; and therefore provide a higher storage capacity. Furthermore, in a memory device having three-dimensional NAND memory arrays, transistors in memory cells are spaced out, and therefore interference and electron leaks can be reduced.

In some examples, memory cells can be grouped into memory blocks. FIG. 2C depicts groupings of NAND strings 206 into blocks of memory cells 250, e.g., blocks of memory cells 250₀-250_{L}. Blocks of memory cells 250 can be groupings of memory cells 208 that can be erased together in a single erase operation. The group of memory cells that can be erased together is also referred to as an erase block. Each block of memory cells 250 can represent those NAND strings 206 commonly associated with a single select line 215, e.g., select line 215₀. The common source 216 for the block of memory cells 250₀ can be a same source as the source 216 for the block of memory cells 250_{L}. For example, each block of memory cells 250₀-250_{L} can be commonly selectively connected to the source 216. Access lines 202 and select lines 214 and 215 of one block of memory cells 250 can have no direct connection to access lines 202 and select lines 214 and 215, respectively, of any other block of memory cells of the blocks of memory cells 250₀-250_{L}.

The bit lines 204₀-204_{M} can be connected (e.g., selectively connected) to a buffer portion 240, which can be a portion of the page buffer 152 of the memory device 130. The buffer portion 240 can correspond to a memory plane (e.g., the set of blocks of memory cells 250₀-250_{L}). The buffer portion 240 can include sense circuits (which can include sense amplifiers) for sensing data values indicated on respective bit lines 204.

FIG. 2D is a block schematic of a portion of an example array of memory cells 260. Array of memory cells 260 can be used as the array of memory cells 104 in a memory device 130. The array of memory cells 260 is depicted as having four memory planes 261 (e.g., memory planes 261a-261d). Each of the memory planes 261 may refer to a group of memory blocks of memory cells 250. Each memory plane 261 can be in communication with a respective buffer portion 240, which can collectively form a page buffer 262. Page buffer 262 may be used to implement page buffer 152 shown in FIG. 1. While four memory planes 261 are depicted, other numbers of memory planes 261 can be commonly in communication with a page buffer 262. Each memory plane 261 is depicted to include L+1 blocks of memory cells 250 (e.g., blocks of memory cells 250₀-250_{L}).

In some cases, concurrent operations may be performed on different planes. For example, concurrent operations may be performed on memory cells within different blocks 250 so long as the different blocks 250 are in different planes 261. In some cases, an individual memory block 250 may be referred to as a physical block, and a virtual block may refer to a group of blocks 250 within which concurrent operations may occur. For example, concurrent operations may be performed on four blocks of 250₀ that are within planes 261a, 261b, 261c, and 261d, respectively, and the four blocks of 250₀ may be collectively referred to as a virtual block. In some cases, a virtual block may include blocks from different memory devices. In some cases, the physical blocks within a virtual block may have the same block address within their respective planes. In some cases, performing concurrent operations in different planes 261 may be subject to one or more restrictions, such as concurrent operations being performed on memory cells within different pages that have the same page address within their respective planes 261 (e.g., related to command decoding, page address decoding circuitry, or other circuitry being shared across planes 261).

In some cases, a block 250 may include memory cells organized into rows (pages) and columns (e.g., strings, not shown). For example, memory cells in a same page may share (e.g., be coupled with) a common word line, and memory cells in a same string may share (e.g., be coupled with) a common data line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page may be the smallest unit of memory (e.g., set of memory cells) that may be independently programmed or read (e.g., programed or read concurrently as part of a single program or read operation), and a memory block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page may, in some cases, not be updated until the entire block that includes the page has been erased.

With continued reference to FIGS. 1 and 2A-2C, during a true erase operation (during which memory cells are actually being erased), the local controller 135 can cause a common source voltage line, e.g., the SRC 216 (FIG. 2A), to be ramped to an erase voltage (VERA or Vera) with an erase pulse while the select gates 210₀ to 210_{M} (SGS transistors) are turned on. Ramping to this high bias erase voltage, and the subsequent recovery from this voltage ramping, may take a significant amount of time. Concurrently, the local controller 135 can cause the select gates 212₀ to 212ₘ (FIG. 2A) to be turned off to enable the drains of the select gates 212₀ to 212ₘ to float, which causes the bit lines 204₀ to 204_{M} to also float. Further, the local controller 135 can cause the word lines 202 (FIG. 2A) to be coupled to ground, e.g., zero volts, or cause the word lines 202 to be maintained at a low voltage. This set of voltage levels at the memory array 200A can create an erase potential that causes the memory cells 208₀ to 208_{N} to be erased, e.g., forces electrons to exit through a body of each memory cell and out the floating bit lines 204₀ to 204_{M}. In other embodiments, the reverse can be done so the select gates 210₀ to 210_{M} are turned off, causing the SRC line 216 to float while the voltage of the bit lines are ramped to Vera while the select gates 212₀ to 212_{M} are turned on. As mentioned earlier, in 3D NAND, one of the channel region, pillar, or bit line can also be ramped up in voltage to cause erasure of attached memory cells. In some embodiments, one or more sub-blocks, to include a physical block, of memory cells are erased during the same true erase operation. A block of memory cells can be generally understood to include four or more sub-blocks, wherein each sub-block includes a separate string of memory cells.

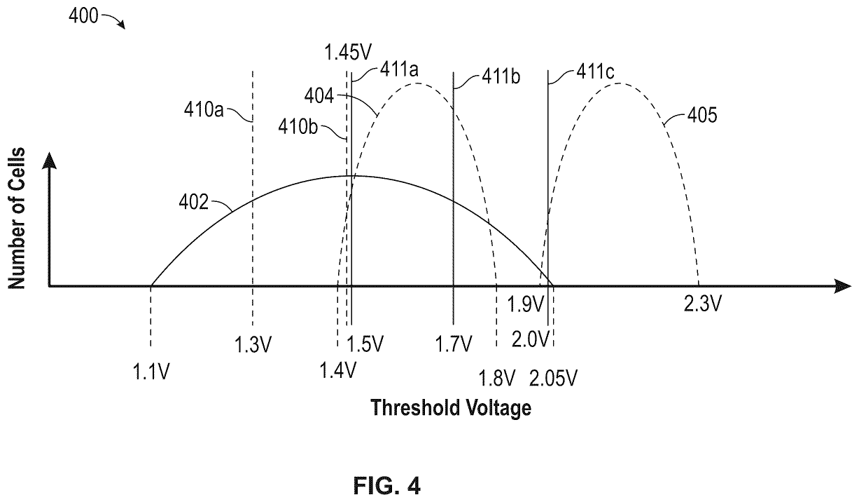

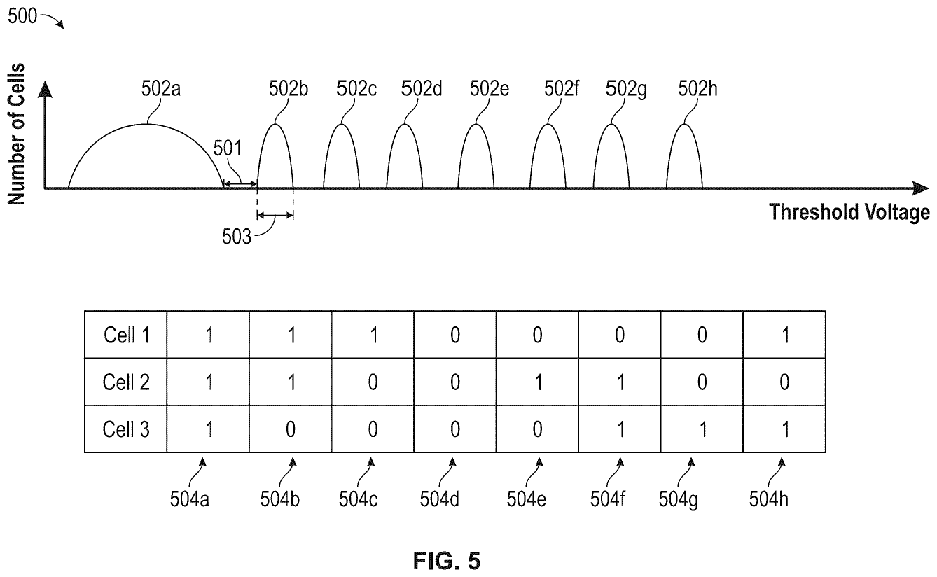

With continued reference to FIGS. 1 and 2A-2C, the array of memory cells 104 may be configured to store data at multiple logical levels. In some embodiments, the local controller 135 may be configured to cause one or more memory cells of the array of memory cells 104 to be programmed to a particular logical level (e.g., a present logical level). Each of the logical levels may correspond to different verification levels used to verify the cell distribution of the threshold voltages. An example of cell distributions of example logical levels is described below in relation to FIG. 5. As described above, in some embodiments, a particular verification level of a lower logical level may be the same, similar to, or close to another verification level of a greater logical level. An example of verification levels that correspond to different logical levels while being the same, similar to, or close to each other is described below in relation to FIG. 4. These same or similar verification levels of different logical levels can be used to accurately determine cell distribution of threshold voltages without the cost of additional time delay.

In some examples, the local controller 135 is configured to cause information regarding multiple logical levels to be obtained without changing the verification level associated with the word line voltage. The local controller 135 may identify multiple logical levels of the array of memory cells 104 to use for verifying the cell distribution of the threshold voltage of a present logical level of the array of memory cells 104. Accordingly, the local controller 135 may cause the sense amplifier 140 to select the multiple logical levels of the array of memory cells 104 to verify the present logical level of the array of memory cells 104. With the selection of the multiple logical levels, the sense amplifier 140 selects the multiple verification levels corresponding to the multiple logical levels.

The bias control circuit 137 may cause the regulator 109 to apply the word line voltage (e.g., a bias voltage) at the corresponding word lines 202 at a verification level that corresponds to one of the identified logical levels. In some embodiments, the bias control circuit 137 causes the regulator 109 to apply the word line voltage at the corresponding word lines 202 at a verification level that corresponds to the lower logical level of the identified logical levels. Additionally or alternatively, the bias control circuit 137 may cause the regulator 109 to apply data line voltages (e.g., bias voltages) to the corresponding data lines 204 (e.g., bit lines) that correspond to either of the identified logical levels, such that the sense amplifier 140 can sense the current of the bit lines.

The memory cells of the array of memory cells 104 along the corresponding word lines 202 may receive the word line voltage at the verification level. In addition, the memory cells of the array of memory cells 104 along the corresponding data lines 204 may receive the data line voltages. The array of memory cells 104 can conduct current on the data lines 204 based on the current logical level of the memory cells, the verification level of the word line voltage, and/or the data line voltage. The current is sensed by the sense amplifier 140.

The sense amplifier 140 may include a sense amplifier register 241 (shown in FIG. 2C) and/or circuits (e.g., transistors, amplifier, current source, etc.) that are configured to sense the current on the corresponding bit lines 204. In some embodiments, the sense amplifier 140 may wait a period of time to permit the regulator 109 to pre-charge the corresponding word lines 202 to the corresponding verification level. In addition, the sense amplifier 140 may wait another period of time to permit a circuit voltage of the sense amplifier 140 to develop. For example, the sense amplifier 140 may wait the another period of time to sense the current on the corresponding bit lines 204 and permit the node voltage at its input node to be reduced or drop due to the current on the corresponding bit lines 204. The circuit voltage may include any appropriate node voltage within the sense amplifier 140 that may change based on whether there is current on the corresponding data lines 204. For example, the circuit voltage may include a voltage at a collector (Vcc) or an input voltage of the sense amplifier 140.

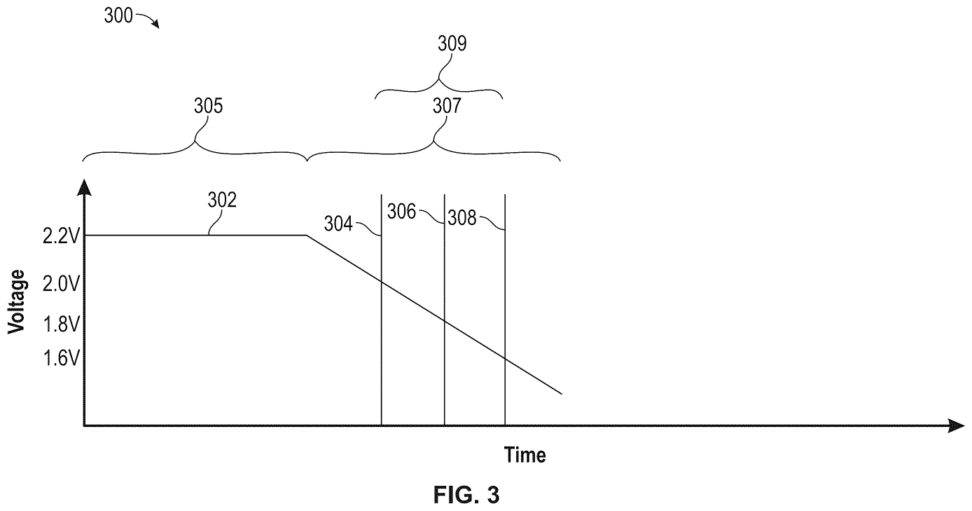

The sense amplifier 140, after the corresponding word lines 202 are pre-charged and the circuit voltage develops, can determine the circuit voltage at different points in time. The different points in time correspond to the different verification levels of the identified logical levels. Based on the determined circuit voltage at the different points in time, information corresponding to multiple logical levels can be determined while the regulator 109 applies the word line voltage at a verification level that corresponds to a single logical level. In particular, based on the determined circuit voltage of the sense amplifier at the different points in time, the controller can determine information corresponding to the FPPV voltage and the PV voltage corresponding to a lower logical level and the SPPV voltage corresponding to the greater logical level, while the regulator 109 applied the word line voltage at a verification level that corresponds to the lower logical level. An example of a developing circuit voltage, which is being determined (e.g., sensed) at different points in time that correspond to verification levels of multiple logical levels is described below in relation to FIG. 3.

FIG. 3 illustrates a graphical representation 300 of a circuit voltage 302 over a period of time during verification of cell distribution of threshold voltages. In the graphical representation 300, the Y axis represents a voltage level of the circuit voltage, and the X axis represents time. As described above, the circuit voltage 302 may be a node voltage associated with the sense amplifier 140 (e.g., an input node voltage). A level of the circuit voltage 302 may change over a period of time due to the change of current on corresponding bit lines of an array of memory cells. In some examples as shown in FIG. 3, the period of time includes a pre-charge portion 305, a develop portion 307, or a sense portion 309.

During the pre-charge portion 305, the local controller 135 causes a word line voltage corresponding to a lower logical level to be applied to the word lines. During the pre-charge portion 305, the word line reaches a pre-configured word line voltage and settles. Permitting the word line voltage to settle may permit the circuit voltage 302 to settle at a steady state operating level. As shown in the example, the steady state operating level is 2.2V.

During the develop portion 307, the circuit voltage 302, if the bit lines are conducting current, may start to drop (e.g., be pulled down). In addition, during the develop portion 307, the circuit voltage 302 may continue to drop until it reaches a reduced steady state operating level (not shown in FIG. 3). If the bit lines are not conducting current, the circuit voltage 302 may not drop.

During the sense portion 309, the sense amplifier 140 may determine the circuit voltage 302 at the different points in time 304, 306, and 308. The sense portion 309 is shown as overlapping part of the develop portion 307 to permit the circuit voltage 302 to be determined at three different points in time 304, 306, and 308 while the circuit voltage 302 is dropping. As shown in FIG. 3, the circuit voltage 302 determined by the sense amplifier 140 at the first point in time is 2.0V, at the second point in time is 1.8V, and at the third point in time is 1.6V.

As described in more detail next, the sense amplifier 140 may compare the determined circuit voltage 302 at the different points in time 304, 306, and 308 to corresponding threshold values to determine if the bit lines are conducting current.

With reference back to FIG. 2C, in some examples, the sense amplifier 140 can compare the circuit voltage sensed at the different points in time to threshold voltages of the memory cells. The threshold voltages are related to the corresponding verification levels. For example, if the circuit voltages of the sense amplifier 140 at one or more of the different points in time are equal to or less than corresponding threshold voltages, the array of memory cells 104 may be conducting current on the bit lines 204 at the corresponding verification levels of the logical level. Alternatively, if the circuit voltage at one or more of the different points in time are greater than the corresponding threshold voltages, the array of memory cells 104 may not be conducting current on the bit lines 204 at the corresponding verification levels of the logical level.

The sense amplifier 140 may store information or cause information to be stored. The information represents whether the array of memory cells 104 are conducting current on the bit lines 204 at the corresponding verification levels of the word line voltage. In some embodiments, the sense amplifier 140 may store information or cause information to be stored as logical 1s or logical 0s in the registers 121, the cache register 118, the sense amplifier register 241, or some combination thereof. For example, the sense amplifier 140 may store information corresponding to the SPPV voltage of the greater logical level in the sense amplifier register 241. As another example, the sense amplifier 140 may cause information corresponding to the FPPV voltage of the lower logical level to be stored in the cache register 118 or an additional register 243 of the registers 121. As yet another example, the sense amplifier 140 may cause information corresponding to the FPPV voltage of the lower logical level to be stored in the cache register 118 or the additional register 243.

In some examples, the local controller 135, in accordance with the stored information, causes the regulator 109 to adjust the bit line voltages for subsequent programming loops to maintain or reduce an amount that the current on the bit lines 204 can change, or to prevent or inhibit a change in the current on the bit lines 204. The local controller 135, in accordance with the stored information, may cause the regulator 109 to adjust the bit line voltages (e.g., increasing or decreasing the bit line voltages) to cause a general process to occur, a first speed-down process to occur, a second speed-down process to occur, or an inhibit process to occur.

In some embodiments, in a general process, the regulator 109 increases the bit line voltages by a general amount. When the bit line voltages are increased by a general amount, the current on the bit lines 204 may be reduced. In the first speed-down process, the regulator 109 increases the bit line voltages by a first speed-down amount. In some embodiments, the first speed-down amount is less than the general amount. Thus, when the first speed-down amount is used, the current on the bit lines 204 may be less reduced or maintained compared to increasing the bit line voltages by the general amount. Further, in the second speed-down process, the regulator 109 increases the bit line voltages by a second speed-down amount. In some embodiments, the second speed-down amount is greater than the first speed-down amount. Thus, when the second speed-down amount is used, the current on the bit lines 204 may be further reduced compared to if the first speed-down amount is used. In the inhibit process, the regulator increases the bit line voltages by an amount to inhibit the array of memory cells 104 from being programmed. In some embodiments, the general amount, the first speed-down amount, the second speed-down amount, or the amount to inhibit the array of memory cells 104 can be based on pre-determined fuse trim values of the memory device 130. It is understood that the amount of changes applied to the bit line voltages can be configured in any desired manner and not limited to the above-described ways.

In other embodiments, in a general process, the regulator 109 decreases the bit line voltages by a general amount. When the bit line voltages are decreased by a general amount, the current on the bit lines 204 may be reduced. In the first speed-down process, the regulator 109 decreases the bit line voltages by a first speed-down amount. In some embodiments, the first speed-down amount is less than the general amount. Thus, when the first speed-down amount is used, the current on the bit lines 204 may be less reduced or maintained compared to decreasing the bit line voltages by the general amount. Further, in the second speed-down process, the regulator 109 decreases the bit line voltages by a second speed-down amount. In some embodiments, the second speed-down amount is greater than the first speed-down amount. Thus, when the second speed-down amount is used, the current on the bit lines 204 may be further reduced compared to if the first speed-down amount is used. In the inhibit process, the regulator decreases the bit line voltages by an amount to inhibit the array of memory cells 104 from being programmed. In some embodiments, the general amount, the first speed-down amount, the second speed-down amount, or the amount to inhibit the array of memory cells 104 can be based on pre-determined fuse trim values of the memory device 130. It is understood that the amount of changes applied to the bit line voltages can be configured in any desired manner and not limited to the above-described ways.

As described above, in a memory device, a particular logical level can correspond to multiple verification levels of the word line voltage. The particular level of the word line voltage can affect the bit line currents of the memory cells connected to the particular word line. Additionally, the voltage of the bit lines can be adjusted according to the method described above to control an amount the word line voltage affects the bit line currents. Verification of the threshold voltages of the memory cells is performed by sensing the circuit voltages as a function of the bit line currents. For verifying the cell distribution of the threshold voltages, two different logical levels may be selected. As described above, they may correspond to a same or similar verification level.

FIG. 4 illustrates a graphical representation 400 of example cell distributions 402, 404, and 405 and example verification levels 410a-b and 411a-c that correspond to various logical levels. In the graphical representation 400, the Y axis represents a number of cells in the memory array and the X axis represents the threshold voltage. In FIG. 4, the example verification level 410a corresponds to 1.3V and the example verification level 410b corresponds to 1.45V. In addition, in FIG. 4, the example verification level 411a corresponds to 1.5V, the example verification level 411b corresponds to 1.7V, and the example verification level 411c corresponds to 2.0V.

As shown in FIG. 4, the cell distribution 404 represents a verified distribution of a threshold voltage corresponding to a first logical level. The cell distribution 402 represents a non-verified distribution of a threshold voltage corresponding to the first logical level and a second logical level. Further, the cell distribution 405 represents a verified distribution of a threshold voltage corresponding to the second logical level. In the example shown, the cell distribution 402 includes a range between 1.1V and 2.05V, the cell distribution 405 includes a range between 1.9V and 2.3V, and the cell distribution 404 includes a range between 1.4V and 1.8V

As shown in FIG. 4, the cell distribution 402 includes a larger range than the cell distribution 405 because threshold verification has not been performed to reduce the range of the cell distribution 405. Further, in this example, the cell distribution 402 completely overlaps the cell distribution 404 corresponding to the first logical level. The overlap of the cell distributions 402 and 404 may result in errors when trying to read data, store data, or both, if the cell distribution 402 is not verified.

To reduce the risk of errors being introduced when trying to read data, store data, or both, threshold verification may be performed using the multiple verification levels 410a-b and 411a-c or additional verification levels in accordance with the processes described in the present disclosure. For example, the sense amplifier 140 may determine the circuit voltage (e.g., an input node voltage) at different points in time corresponding to at least the verification levels 410b and 411a while the local controller 135 causes a single word line voltage corresponding to the first logical level to be applied to reduce a width of the cell distribution 402 to result in the cell distribution 404.

In this example shown in FIG. 4, a difference between the verification levels 410a-b and 411a (e.g., a difference between three verification levels corresponding to two logical levels) may be less than the difference between the verification levels 411a-c (e.g., a difference between three verification levels corresponding to a single logical level). As shown, the difference between the verification levels 410a-b and 411a is approximately equal to 0.2V (e.g., 1.5V−1.3V=0.2V), whereas the difference between the verification levels 411a-c is approximately equal to 0.5V (e.g., 2.0V−1.5V=0.5V).

Because the difference between the verification levels 410a-b and 411a is small enough, the difference of the circuit voltages at corresponding multiple points in time caused by the different verification levels 410a-b and 411a is with the sensing range capability of the sense amplifier 140. As a result, the sense amplifier 140 can determine the circuit voltage at different points in time corresponding to all three verification levels 410a-b and 411a while the local controller 135 causes a single word line voltage to be applied. Thus, the sense amplifier 140 can sense the circuit voltage at multiple points in time that correspond to the three verification levels 410a-b and 411a while the local controller 135 causes a single word line voltage corresponding to the first logical level to be applied to the array of memory cells. The verification efficiencies is improved without requiring the sense amplifier to have a large sensing ranging capability.

In FIG. 4, the verification level 410a corresponds to the PPV voltage of the first logical level and the verification level 410b corresponds to the PV voltage of the first logical level. Further, in FIG. 4, the verification level 411a corresponds to the SPPV voltage of the second logical level, the verification level 411b corresponds to the PPV voltage of the second logical level, and the verification level 411c corresponds to the PV voltage of the second logical level. The presently-disclosed technologies allow the sensing at multiple verification levels corresponding to multiple logical levels, greatly improving the efficiency while maintaining or improving the sensing accuracy.

The technologies of sensing at multiple verification levels corresponding to multiple logical levels are described more using Table 1, which provides an example of verifying the threshold voltages of the array of memory cells 104 when they are configured to be programmed according to Table 1.

TABLE 1

| | Erase | | | | | | | |
|---|---|---|---|---|---|---|---|---|
| | Logical | Logical | Logical | Logical | Logical | Logical | Logical | Logical |
| | Level | Level 1 | Level 2 | Level 3 | Level 4 | Level 5 | Level 6 | Level 7 |
| Cell 1 | 1 | 1 | 1 | 0 | 0 | 0 | 0 | 1 |
| Cell 2 | 1 | 1 | 0 | 0 | 1 | 1 | 0 | 0 |
| Cell 3 | 1 | 0 | 0 | 0 | 0 | 1 | 1 | 1 |

With reference to Table 1, a controller (e.g., the local controller 135) may identify, for example, the logical level 1 and the logical level 2 to use for verifying the cell distribution of the threshold voltage of the present logical level of the array of memory cells 104. Similar to shown above in FIG. 4, the logical level 1 may include a SPPV voltage at a first level, an FPPV voltage at a second level, and a PV voltage at a third level. Additionally, the logical level 2 may include a SPPV voltage at a fourth level, an FPPV voltage at a fifth level, and a PV voltage at a sixth level. In this example, the third level of the PV voltage of the logical level 1 may be the same, similar to, or close to the fourth level of the SPPV voltage of the logical level 2. That is, the PV voltage of logical level 1 may be the same or similar to the SPPV voltage of logical level 2 (similar to the level 410b is close to level 411a shown in FIG. 4).

During the verification operation for the identified logical levels 1 and 2, the regulator 109 may apply a word line voltage to the word lines 202 at the third level (e.g., the PV voltage) of the logical level 1. In some embodiments, the regulator 109 may change the data line voltages of the data lines 204 between levels that correspond to the logical level 1 or the logical level 2. The sense amplifier 140 may determine the circuit voltage of the sense amplifier 140 at the first point in time, which corresponds to the PV voltage of the logical level 1. The sense amplifier 140 may also determine the circuit voltage of the sense amplifier 140 at the second point in time, which corresponds to the FPPV voltage of the logical level 1. In addition, the sense amplifier 140 may determine the circuit voltage of the sense amplifier 140 at the third point in time, which corresponds to the SPPV voltage of the logical level 2. As described above, the SPPV voltage of logical level 2 may be the same or similar to the PV voltage of logical level 1.

The sense amplifier 140 may compare the circuit voltage at the first point in time to a first threshold voltage that corresponds to the FPPV voltage of the logical level 1 to determine if particular memory cells in the array of memory cells 104 are conducting current at the FPPV voltage. Additionally, the sense amplifier 140 may compare the circuit voltage at the second point in time to a second threshold voltage that corresponds to the PV voltage of the logical level 1 to determine if the particular memory cells are conducting current at the PV voltage. Further, the sense amplifier 140 may compare the circuit voltage at the third point in time to a third threshold voltage that corresponds to the SPPV voltage of the logical level 2 to determine if the array of memory cells 104 are conducting current at the SPPV voltage.

The sense amplifier 140 may store information representative of whether the particular memory cells are conducting current on the bit lines 204 at the FPPV voltage and the PV voltage of the logical level 1 and the SPPV voltage of the logical level 2 to the registers 121, the cache register 118, the sense amplifier register 241, or some combination thereof (generally referred to in the present disclosure as the information registers). For example, if the sense amplifier 140 determines that the particular memory cells are conducting current on the bit lines 204 at the FPPV voltage, the PV voltage, or the SPPV voltage, the sense amplifier 140 may store a logical 0 at a corresponding register. Alternatively, if the sense amplifier 140 determines that the array of memory cells 104 are not conducting current on the bit lines 204 at the FPPV voltage, the PV voltage, or the SPPV voltage, the sense amplifier 140 may store a logical 1 at the corresponding register.

Examples of storing information representative of whether the memory cells are conducting current on the bit lines 204 for the verification levels corresponding to the logical level 1 will now be discussed. If the memory cells are conducting current on the bit lines 204 at the SPPV voltage, the FPPV voltage, and the PV voltage corresponding to the logical level 1, the sense amplifier 140 may store a logical sequence of “000” to the information registers. Alternatively, if the memory cells are conducting current on the bit lines 204 at the FPPV voltage and the PV voltage corresponding to the logical level 1 but are not conducting current at the SPPV voltage corresponding to the logical level 1, the sense amplifier 140 may store a logical sequence of “100” to the information registers. Further, if the memory cells are conducting current on the bit lines 204 at the PV voltage corresponding to the logical level 1 but are not conducting current at the SPPV voltage and the FPPV voltage corresponding to the logical level 1, the sense amplifier 140 may store a logical sequence of “110” to the information registers. If the memory cells are not conducting current on the bit lines 204 at the SPPV voltage, the FPPV, and the PV voltage corresponding to logical level 1, the sense amplifier 140 may store a logical sequence of “111” to the information registers.

Returning to the example of verifying the threshold voltages of the array of memory cells 104 when they are configured to be programmed according to Table 1, the local controller 135, in accordance with the stored information, may cause the regulator 109 to adjust the bit line voltages applied to the bit lines 204 for a subsequent programming loop to capture remaining information corresponding to the logical level 2 and information corresponding to a logical level 3 (e.g., information for a subsequent programming loop). As discussed above, the local controller 135, in accordance with the information stored in the information registers, may cause the regulator 109 to adjust the bit line voltages of the bit line 204 to cause the first speed-down process to occur, the second speed-down process to occur, the general process to occur, or the inhibit process to occur when capturing the information for the subsequent programming loop.

In some cases, if the stored information indicates that current is being conducted at the SPPV voltage, the FPPV voltage, and the PV voltage corresponding to the logical level 1, the local controller 135 may cause the regulator 109 to adjust the bit line voltages to cause the inhibit process to occur and prevent the memory cells from being programmed for the subsequent programming loops. In other cases, if the stored information indicates that current is being conducted at the FPPV voltage and the PV voltage but not at the SPPV voltage corresponding to logical level 1, the local controller 135 may cause the regulator 109 to adjust the bit line voltages by the first amount to cause the first speed-down process to occur and control the current on the bit lines for the subsequent programming loops. In yet other cases, if the stored information indicates that current is being conducted at the PV voltage but not at the FPPV voltage and the SPPV voltage corresponding to the logical level 1, the local controller 135 may cause the regulator 109 to adjust the bit line voltages by the second amount to cause the second speed-down process to occur and control the current on the bit lines for the subsequent programming loops. In some cases, if the stored information indicates that current is not being conducted at the SPPV voltage, the FPPV, and the PV voltage corresponding to the logical level 1, the local controller 135 may cause the regulator 109 to adjust the bit line voltages by the general amount to cause the general process to occur and control the current on the bit lines for the subsequent programming.

The local controller 135, the regulator 109, and the sense amplifier 140 may repeat the process described above in relation to the logical level 1 and the logical level 2, but in relation to the FPPV voltage and the PV voltage of the logical level 2 and the SPPV voltage of the logical level 3 instead. In addition, the local controller 135, the regulator, and the sense amplifier 140 may repeat the process described above to capture information related to each of logical level 3 through logical level 7. In this manner, the cell distribution of memory cells can be verified.

FIG. 5 illustrates a graphical representation 500 of cell distributions 502a-h of example logical levels 504a-h of three cells of an array of memory cells, in accordance with examples as disclosed herein. In the graphical representation 500, the Y axis represents a number of cells in the memory array (e.g., three cells in the example of FIG. 5) and the X axis represents the threshold voltage.

Each of the cell distributions 502a-h may correspond to a different one of the logical levels 504a-h. For example, the cell distribution 502a corresponds to the logical level 504a, which corresponds to a logical sequence of “111” stored in the cells of the array of memory cells. As another example, the cell distribution 502e corresponds to the logical level 504e, which corresponds to a logical sequence of “010” stored in the cells of the array of memory cells.

As a number of cells in the array of memory cells increases, margins or gaps between the cell distributions 502a-h may become smaller. An example margin is represented by arrow 501 in FIG. 5. If the margins are not present (e.g., two or more of the cell distributions overlap 502a-h), errors may be introduced when reading data, storing data, or both to the array of memory cells. To reduce the likelihood of errors being introduced when reading data, storing data, or both, the cell distributions 502a-h may be verified using threshold voltage verification method described above to reduce a width of the cell distributions 502a-h and increase the margins. An example width of the cell distribution 502b is represented by arrow 503 in FIG. 5. For example, the local controller 135, the sense amplifier 140, or a combination thereof can verify the cell distributions of the cells of the array of memory cells using the processes described in the present disclosure to reduce the width of the cell distributions, to increase the margin between the cell distributions, or both.

It is understood that various systems, apparatus, and methods described herein may be implemented using analog and/or digital circuitry, or using one or more computers using well-known computer processors, memory systems, storage devices, computer software, and other components. Typically, a computer includes a processor for executing instructions and one or more memory systems for storing instructions and data. A computer may also include, or be coupled to, one or more mass storage devices, such as one or more magnetic disks, internal hard disks and removable disks, magneto-optical disks, optical disks, etc.

Various systems, apparatus, and methods described herein may be implemented using computers operating in a client-server relationship. Typically, in such a system, the client computers are located remotely from the server computers and interact via a network. The client-server relationship may be defined and controlled by computer programs running on the respective client and server computers. Examples of client computers can include desktop computers, workstations, portable computers, cellular smartphones, tablets, or other types of computing devices.

Various systems, apparatus, and methods described herein may be implemented using a computer program product tangibly embodied in an information carrier, e.g., in a non-transitory machine-readable storage device, for execution by a programmable processor; and the method processes and steps described herein, including one or more of the steps of at least some of the FIGS. 1-2D, may be implemented using one or more computer programs that are executable by such a processor. A computer program is a set of computer program instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

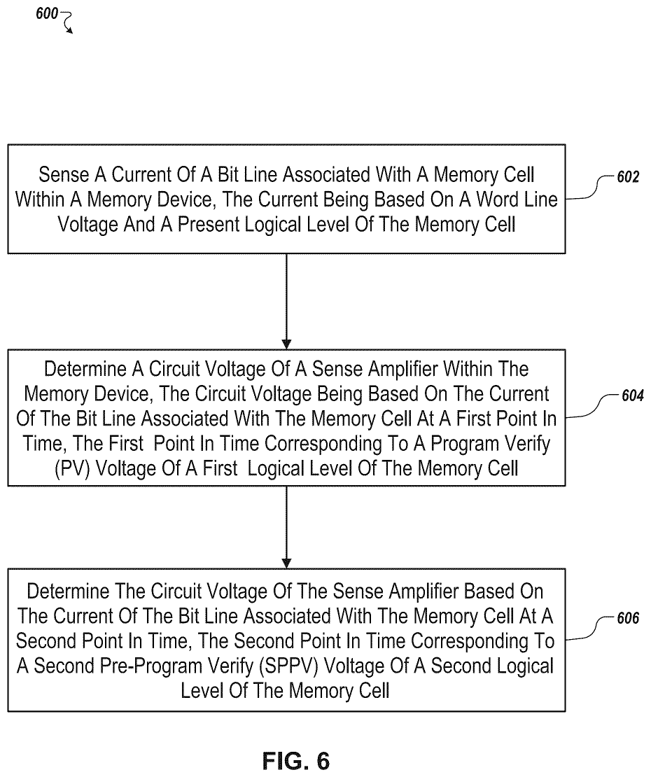

FIG. 6 illustrates a flowchart showing a method 600 that supports techniques for voltage threshold verification using multi-level sensing of a memory cell in accordance with examples as disclosed herein. At least some of the blocks in method 600 can be performed by a sense amplifier (e.g., sense amplifier 140) during verification of a threshold voltage of the memory cell. At block 602, the sense amplifier senses a current of a bit line (e.g., bit lines 204) associated with a memory cell (e.g., array of memory cells 104) within a memory device (e.g., memory device 130). The current may be based on a word line voltage and a present logical level of the memory cell. The word line voltage may be applied by a regulator (e.g., regulator 109) on word lines coupled to the memory cell. In block 604, the sense amplifier determines a circuit voltage of the sense amplifier within the memory device. The circuit voltage may be based on the current of the bit line associated with the memory cell at a first point in time. The first point in time may correspond to a PV voltage of a first logical level of the memory cell. In block 606, the sense amplifier determines the circuit voltage of the sense amplifier based on the current of the bit line associated with the memory cell at a second point in time. The second point in time may correspond to a SPPV voltage of a second logical level of the memory cell.

Method 600 may include additional blocks not shown in FIG. 6. For example, the method 600 may include another block, in which the sense amplifier determines the circuit voltage of the sense amplifier based on the current of the bit line associated with the memory cell at a third point in time. The third point in time may correspond to a FPPV voltage of the first logical level of the memory cell.

It should be noted that the described techniques include possible implementations, and that the operations and the blocks may be rearranged, reordered, or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over, as one or more instructions or code, a computer-readable medium. Other examples and implementations are within the scope of the disclosure and appended claims. For example, due to the nature of software, the described functions can be implemented using software executed by a processor, hardware, firmware, hardwiring, or combinations of any of these. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory device comprising:
a memory cell coupled to a word line, the word line being configured to receive a word line voltage corresponding to a first logical level of the memory cell; and
a page buffer coupled to a bit line associated with the memory cell, the page buffer comprising a sense amplifier configured to:
sense a current of the bit line associated with the memory cell, the current being based on the word line voltage and a present logical level of the memory cell;
determine a circuit voltage of the sense amplifier based on the current of the bit line associated with the memory cell at a first point in time, the first point in time corresponding to a program verify (PV) voltage of the first logical level of the memory cell; and
determine the circuit voltage of the sense amplifier based on the current of the bit line associated with the memory cell at a second point in time, the second point in time corresponding to a second pre-program verify (SPPV) voltage of a second logical level of the memory cell.

2. The memory device of claim 1, wherein the sense amplifier is configured to determine the circuit voltage of the sense amplifier based on the current of the bit line associated with the memory cell at a third point in time, the third point in time corresponding to a first pre-program verify (FPPV) voltage of the first logical level of the memory cell.

3. The memory device of claim 2, wherein:
the word line voltage comprises a first word line voltage;
the memory device comprises a local controller configured to cause a second word line voltage to be applied to the word line coupled to the memory cell, the second word line voltage corresponding to the second logical level; and
the sense amplifier is configured to:
sense the current of the bit line associated with the memory cell, the current being based on the second word line voltage and the present logical level of the memory cell;
determine the circuit voltage of the sense amplifier based on the current of the bit line associated with the memory cell at a fourth point in time, the fourth point in time corresponding to an FPPV voltage of the second logical level of the memory cell;
determine the circuit voltage of the sense amplifier based on the current of the bit line associated with the memory cell at a fifth point in time, the fifth point in time corresponding to a PV voltage of the second logical level of the memory cell; and
determine the circuit voltage of the sense amplifier based on the current of the bit line associated with the memory cell at a sixth point in time, the sixth point in time corresponding to a SPPV voltage of a third logical level of the memory cell.

4. The memory device of claim 2, wherein the sense amplifier is configured to:
compare the circuit voltage at the first point in time to a first threshold voltage, the first threshold voltage corresponding to the PV voltage of the first logical level;
compare the circuit voltage at the second point in time to a second threshold voltage, the second threshold voltage corresponding to the SPPV voltage of the second logical level; and
compare the circuit voltage at the third point in time to a third threshold voltage, the third threshold voltage corresponding to the FPPV voltage of the first logical level.

5. The memory device of claim 4, wherein:
the circuit voltage at the first point in time being less than or equal to the first threshold voltage indicates that the first logical level is the present logical level of the memory cell and that an inhibit process is to be performed;
the circuit voltage at the second point in time being less than or equal to the second threshold voltage indicates that a general process to verify the present logical level of the memory cell is to be performed;
the circuit voltage at the second point in time being greater than the second threshold voltage indicates that a first speed-down process to verify the present logical level of the memory cell is to be performed; and
the circuit voltage at the third point in time being less than or equal to the third threshold voltage indicates that a second speed-down process to verify the present logical level of the memory cell is to be performed.

6. The memory device of claim 5, wherein the memory device comprises a local controller configured to:
cause the inhibit process to be performed comprising causing a bit line voltage being applied to the bit line to be decreased so as to inhibit the memory cell from being programmed;
cause the general process to be performed comprising causing the bit line voltage to be decreased by a general amount;
cause the first speed-down process to be performed comprising causing the bit line voltage to be decreased by a first speed-down amount, the first speed-down amount being less than the general amount; and
cause the second speed-down process to be performed comprising causing the bit line voltage to be decreased by a second speed-down amount, the second speed-down amount being less than the first speed-down amount.

7. The memory device of claim 4, wherein:
the page buffer comprises a sense amplifier register, a cache register, and an additional register; and
the sense amplifier is configured to:
store information corresponding to the SPPV voltage in the sense amplifier register;
cause information corresponding to the FPPV voltage to be stored in at least one of the cache register or the additional register; and
cause information corresponding to the PV voltage to be stored in at least one of the cache register or the additional register.

8. The memory device of claim 1, wherein:
the memory device comprises a local controller and a regulator, the regulator being coupled to the memory cell via the word line;
the local controller is configured to cause the regulator to apply the word line voltage at a voltage level corresponding to the first logical level; and
the circuit voltage is determined at the second point in time to permit information corresponding to the SPPV voltage of the second logical level to be determined using the word line voltage at the voltage level corresponding to the first logical level.

9. A memory device comprising:
a word line configured to receive a word line voltage corresponding to a first logical level of a plurality of memory cells;
a plurality of bit lines;
the plurality of memory cells electrically coupled to the word line and the plurality of bit lines;
a regulator electrically coupled to the word line and configured to apply the word line voltage; and
a page buffer electrically coupled to the plurality of memory cells via the plurality of bit lines, the page buffer comprising a sense amplifier configured to:
sense a current of the plurality of bit lines, the current being based on the word line voltage and a present logical level of the plurality of memory cells;
determine a circuit voltage of the sense amplifier based on the current of the plurality of bit lines at a first point in time, the first point in time corresponding to a first pre-program verify (FPPV) voltage of the first logical level of the plurality of memory cells;
determine the circuit voltage of the sense amplifier based on the current of the plurality of bit lines at a second point in time, the second point in time corresponding to a program verify (PV) voltage of the first logical level of the plurality of memory cells; and
determine the circuit voltage of the sense amplifier based on the current of the plurality of bit lines at a third point in time, the third point in time corresponding to a second pre-program verify (SPPV) voltage of a second logical level of the plurality of memory cells.

10. The memory device of claim 9, wherein:
the word line voltage comprises a first word line voltage;
the memory device comprises a local controller configured to cause the regulator to apply a second word line voltage to be applied to the word line, the second word line voltage corresponding to the second logical level; and
the sense amplifier is configured to:
sense the current of the plurality of bit lines, the current being based on the second word line voltage and the present logical level of the plurality of memory cells;
determine the circuit voltage of the sense amplifier based on the current of the plurality of bit lines at a fourth point in time, the fourth point in time corresponding to an FPPV voltage of the second logical level of the plurality of memory cells;
determine the circuit voltage of the sense amplifier based on the current of the plurality of bit lines at a fifth point in time, the fifth point in time corresponding to a PV voltage of the second logical level of the plurality of memory cells; and
determine the circuit voltage of the sense amplifier based on the current of the plurality of bit lines at a sixth point in time, the sixth point in time corresponding to a SPPV voltage of a third logical level of the plurality of memory cells.

11. The memory device of claim 9, wherein the sense amplifier is configured to:
compare the circuit voltage at the first point in time to a first threshold voltage, the first threshold voltage corresponding to the FPPV voltage of the first logical level;
compare the circuit voltage at the second point in time to a second threshold voltage, the second threshold voltage corresponding to the PV voltage of the first logical level; and
compare the circuit voltage at the third point in time to a third threshold voltage, the third threshold voltage corresponding to the SPPV voltage of the second logical level.

12. The memory device of claim 11, wherein:
the circuit voltage at the first point in time being less than or equal to the first threshold voltage indicates that a first speed-down process to verify the present logical level of the plurality of memory cells is to be performed;
the circuit voltage at the second point in time being less than or equal to the second threshold voltage indicates that the first logical level is the present logical level of the plurality of memory cells and that an inhibit process is to be performed;
the circuit voltage at the third point in time being less than or equal to the third threshold voltage indicates that a general process to verify the present logical level of the plurality of memory cells is to be performed; and
the circuit voltage at the third point in time being greater than the second threshold voltage indicates that a second speed-down process to verify the present logical level of the plurality of memory cells is to be performed.

13. The memory device of claim 12, the memory device comprises a local controller configured to:
cause the inhibit process to be performed comprising causing a plurality of bit line voltages being applied to the plurality of bit lines to be decreased so as to inhibit the plurality of memory cells from being programmed;
cause the general process to be performed comprising causing the plurality of bit line voltages to be decreased by a general amount;
cause the first speed-down process to be performed comprising causing the plurality of bit line voltages to be decreased by a first speed-down amount, the first speed-down amount being less than the general amount; and
cause the second speed-down process to be performed comprising causing the plurality of bit line voltages to be decreased by a second speed-down amount, the second speed-down amount being greater than the first speed-down amount.

14. The memory device of claim 9, wherein:
the memory device comprises a local controller configured to cause the regulator to apply the word line voltage at a voltage level corresponding to the first logical level; and
the circuit voltage is determined at the third point in time to permit information corresponding to the SPPV voltage of the second logical level to be determined using the voltage level corresponding to the first logical level.

15. A method comprising:
sensing a current of a bit line associated with a memory cell within a memory device, the current being based on a word line voltage and a present logical level of the memory cell;
determining a circuit voltage of a sense amplifier within the memory device, the circuit voltage being based on the current of the bit line associated with the memory cell at a first point in time, the first point in time corresponding to a program verify (PV) voltage of a first logical level of the memory cell; and
determining the circuit voltage of the sense amplifier based on the current of the bit line associated with the memory cell at a second point in time, the second point in time corresponding to a second pre-program verify (SPPV) voltage of a second logical level of the memory cell.

16. The method of claim 15 further comprising determining the circuit voltage of the sense amplifier based on the current of the bit line associated with the memory cell at a third point in time, the third point in time corresponding to a first pre-program verify (FPPV) voltage of the first logical level of the memory cell.

17. The method of claim 16, wherein:
the word line voltage comprises a first word line voltage;
the method further comprises:
causing a second word line voltage to be applied to the memory cell, the second word line voltage corresponding to the second logical level; and
sensing the current of the bit line associated with the memory cell, the current being based on the second word line voltage and the present logical level of the memory cell;
determining the circuit voltage of the sense amplifier based on the current of the bit line associated with the memory cell at a fourth point in time, the fourth point in time corresponding to an FPPV voltage of the second logical level of the memory cell;
determining the circuit voltage of the sense amplifier based on the current of the bit line associated with the memory cell at a fifth point in time, the fifth point in time corresponding to a PV voltage of the second logical level of the memory cell; and
determining the circuit voltage of the sense amplifier based on the current of the bit line associated with the memory cell at a sixth point in time, the sixth point in time corresponding to a SPPV voltage of a third logical level of the memory cell.

18. The method of claim 16 further comprising:
comparing the circuit voltage at the first point in time to a first threshold voltage, the first threshold voltage corresponding to the PV voltage of the first logical level;
comparing the circuit voltage at the second point in time to a second threshold voltage, the second threshold voltage corresponding to the SPPV voltage of the second logical level; and
comparing the circuit voltage at the third point in time to a third threshold voltage, the third threshold voltage corresponding to the FPPV voltage of the first logical level.

19. The method of claim 18, wherein:
in accordance with the circuit voltage at the first point in time being less than or equal to the first threshold voltage, the method further comprises causing a bit line voltage being applied to the memory cell to be decreased to inhibit the memory cell from the being programmed;
in accordance with the circuit voltage at the second point in time being less than or equal to the second threshold voltage, the method further comprises causing the bit line voltage to be decreased by a general amount;
in accordance with the circuit voltage at the second point in time being greater than the second threshold voltage, the method further comprises causing the bit line voltage to be decreased by a first speed-down amount; and
in accordance with the circuit voltage at the third point in time being less than or equal to the third threshold voltage, the method further comprises causing the bit line voltage to be decreased by a second speed-down amount, the second speed-down amount being less than the first speed-down amount.

20. The method of claim 18 further comprising:
storing information corresponding to the SPPV voltage in a sense amplifier register;
storing information corresponding to the FPPV voltage in at least one of a cache register or an additional register; and
storing information corresponding to the PV voltage in at least one of the cache register or the additional register.
